(19) United States
(12) Patent Application Publication
(10) Pub. No.: US 2026/0344375 A1
(43) Pub. Date: Oct. 29, 2026

(54) REPAIRING LOW-K MATERIALS AFTER INTEGRATION OPERATIONS

(71) Applicant: Applied Materials, Inc., Santa Clara, CA (US)

(72) Inventors: Xinyi Lu, Santa Clara, CA (US); Bo Xie, San Jose, CA (US); Chi-I Lang, Cupertino, CA (US); Li-Qun Xia, Cupertino, CA (US)

(73) Assignee: Applied Materials, Inc., Santa Clara, CA (US)

(21) Appl. No.: 19/184,464

(22) Filed: Apr. 21, 2025

(51) Int. Cl. H01L 21/3105; H01L 21/02

(52) U.S. Cl. CPC H10P 95/00; H10P 70/23

(57) ABSTRACT

Exemplary methods of semiconductor processing may include providing a treatment precursor to a processing region of a semiconductor processing chamber. A substrate may be housed within the processing region. An exposed region of a silicon-containing material and an exposed region of a metal-containing material may be disposed on the substrate. The methods may include directing an ultraviolet (UV) light source into the processing region, wherein the UV light source forms radicals of the treatment precursor. The methods may include contacting the substrate with the radicals of the treatment precursor. The contacting may at least partially repair the silicon-containing material.

### TECHNICAL FIELD

The present technology relates to methods and systems for semiconductor processing. More specifically, the present technology relates to methods for repairing silicon-containing after integration operations.

### BACKGROUND

Integrated circuits are made possible by processes which produce intricately patterned material layers on substrate surfaces. Producing patterned material on a substrate requires controlled methods for forming and removing material. As device sizes continue to reduce, film characteristics may lead to larger impacts on device performance. Materials used to form layers of materials may affect operational characteristics of the devices produced. As material thicknesses continue to reduce, characteristics of the films may have a greater impact on device performance.

Thus, there is a need for improved systems and methods that can be used to produce high quality devices and structures. These and other needs are addressed by the present technology.

### SUMMARY

Exemplary methods of semiconductor processing may include providing a treatment precursor to a processing region of a semiconductor processing chamber. A substrate may be housed within the processing region. An exposed region of a silicon-containing material and an exposed region of a metal-containing material may be disposed on the substrate. The methods may include directing an ultraviolet (UV) light source into the processing region, wherein the UV light source forms radicals of the treatment precursor. The methods may include contacting the substrate with the radicals of the treatment precursor. The contacting may at least partially repair the silicon-containing material.

In embodiments, the treatment precursor may be or include a carbon-containing precursor. The treatment precursor may be or include a hydrocarbon or an alcohol. The treatment precursor may be silicon-free. The metal-containing material may be or include a copper-containing material, a cobalt-containing material, a nickel-containing material, an aluminum-containing material, a ruthenium-containing material, a molybdenum-containing material, or a tungsten-containing material. Contacting the substrate with the radicals of the treatment precursor may form a layer of carbon-containing material on the exposed region of the silicon-containing material. Contacting the substrate with the radicals of the treatment precursor may reduce a dielectric constant of the silicon-containing material by greater than or about 10%. The dielectric constant of the silicon-containing material, subsequent to contacting the substrate with the radicals of the treatment precursor, may be less than or about 3.0. A temperature within the processing region may be maintained at greater than or about 50° C. A pressure within the processing region may be maintained at less than or about 50 Torr.

Some embodiments of the present technology may encompass semiconductor processing methods. The methods may include providing a carbon-containing treatment precursor and a hydrogen-containing precursor to a processing region of a semiconductor processing chamber. A substrate may be housed within the processing region. An exposed region of a silicon-containing material and an exposed region of a metal-containing material may be disposed on the substrate. The methods may include forming radicals of the carbon-containing treatment precursor and the hydrogen-containing precursor. The methods may include contacting the substrate with the radicals of the carbon-containing treatment precursor and the hydrogen-containing precursor. The contacting may at least partially repair the silicon-containing material.

In embodiments, the carbon-containing treatment precursor may be silicon-free. The radicals of the carbon-containing treatment precursor and the hydrogen-containing precursor may be formed using RF power. The RF power may be pulsed. Contacting the substrate with the radicals of the carbon-containing treatment precursor and the hydrogen-containing precursor may reduce a dielectric constant of the silicon-containing material by greater than or about 0.1.

Some embodiments of the present technology may encompass semiconductor processing methods. The methods may include providing a carbon-containing treatment precursor to a processing region of a semiconductor processing chamber. A substrate may be housed within the processing region. An exposed region of a silicon-containing material and an exposed region of a metal-containing material may be disposed on the substrate. The methods may include forming radicals of the carbon-containing treatment precursor. The methods may include contacting the substrate with the radicals of the carbon-containing treatment precursor. The contacting may at least partially repair the silicon-containing material. The methods may include, subsequent to contacting the substrate with the radicals of the carbon-containing treatment precursor, performing a post-treatment operation. The post-treatment operation may include providing a hydrogen-containing precursor to the processing region, forming radicals of the hydrogen-containing precursor, and contacting the substrate with the radicals of the hydrogen-containing precursor. The contacting may remove a carbon-containing material deposited while contacting the substrate with the radicals of the carbon-containing treatment precursor.

In embodiments, the carbon-containing treatment precursor may further include silicon. The radicals of the carbon-containing treatment precursor and/or the hydrogen-containing precursor may be formed using an ultraviolet (UV) light source directed into the processing region. The UV light source may be pulsed. Contacting the substrate with the radicals of the carbon-containing treatment precursor may increase a surface carbon concentration of the silicon-containing material by greater than or about 10 at. %.

Such technology may provide numerous benefits over conventional systems and techniques. For example, embodiments of the present technology may increase carbon concentrations, such as an amount of methyl (—CH₃) groups and therefore reduce dielectric constant, in materials that have been carbon depleted, such as during integration operations. Additionally, the present technology may reduce or prevent a formation of carbon-containing material on exposed metal-containing materials subsequent to increasing carbon concentrations in the materials that have been carbon depleted. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

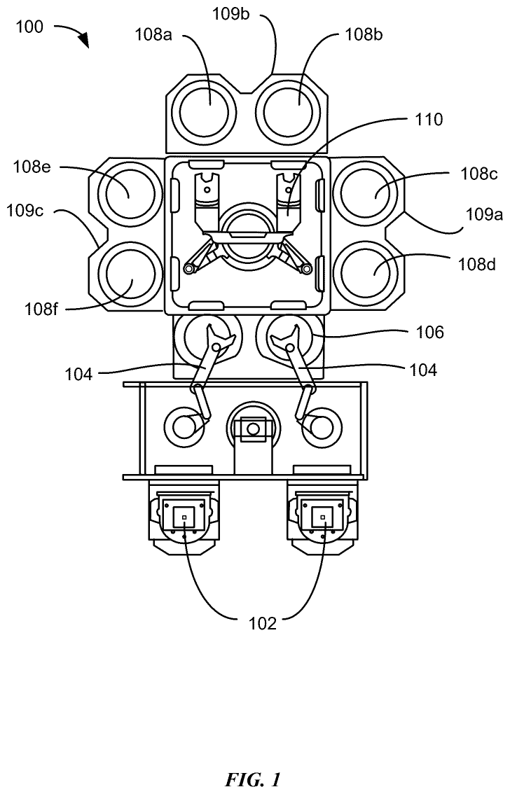

FIG. 1 shows a top plan view of an exemplary processing system according to some embodiments of the present technology.

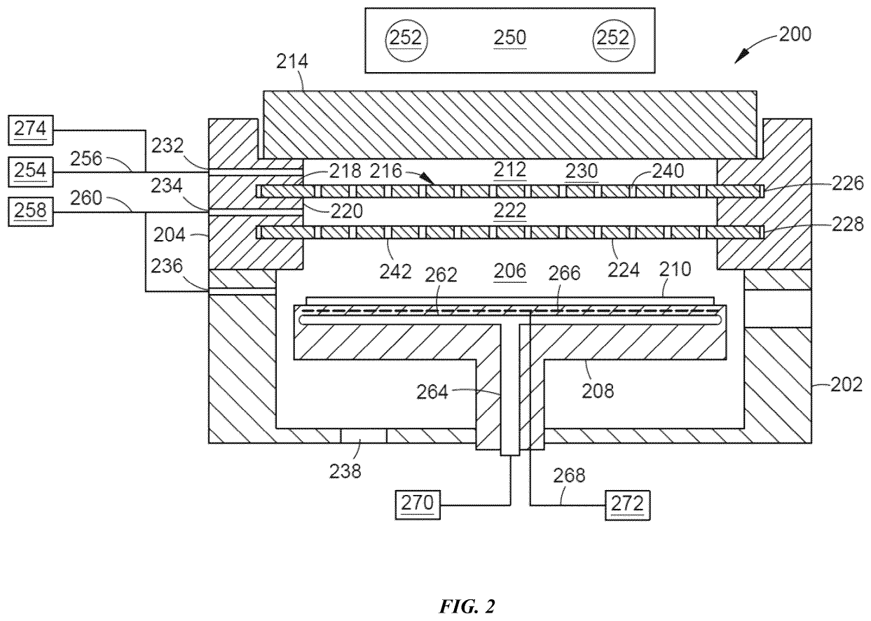

FIG. 2 shows a schematic cross-sectional view of an exemplary semiconductor processing chamber according to some embodiments of the present technology.

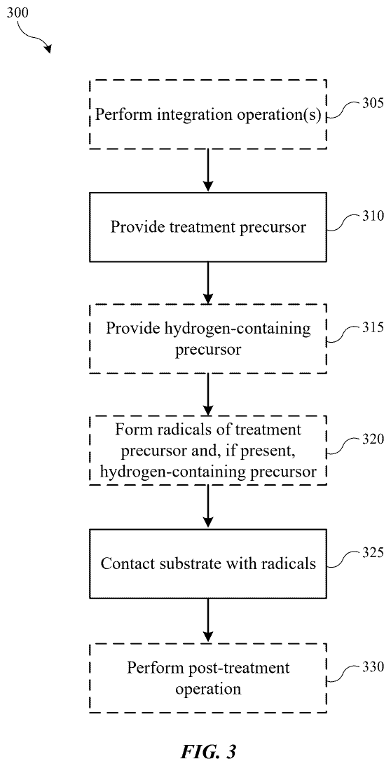

FIG. 3 shows operations in a semiconductor processing method according to some embodiments of the present technology.

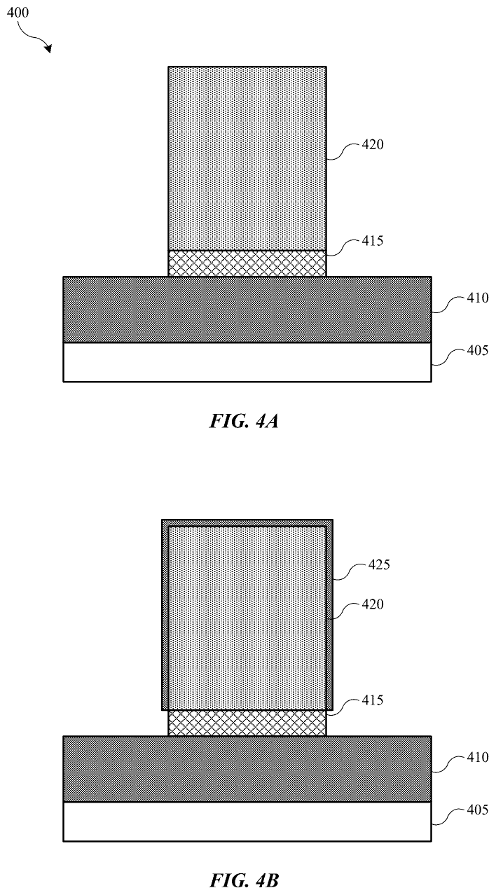

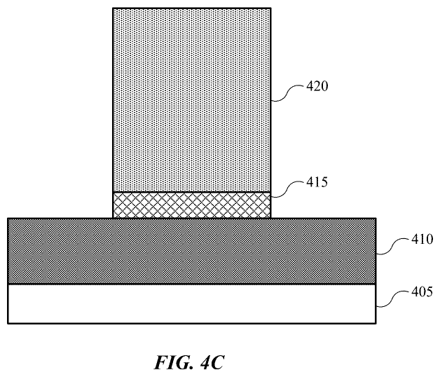

FIGS. 4A-4C show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As semiconductor device sizes continue to reduce, the constituent films included within a structure may affect device performance, as well as fabrication of other materials being included in the device. Additionally, as demand increases, throughput and queue times become a point of emphasis. Thus, a demand exists for high-quality materials and structures that may be formed both quickly and efficiently. In processes to form conformal low dielectric constant silicon-containing materials, such as in gate all around (GAA) applications, increasingly low dielectric constants may be desired. However, various integration operations may reduce the dielectric constant, such as by introducing hydroxyl (—OH) groups to the material. Due to the introduction of —OH groups and resultant depletion of carbon in the silicon-containing materials during integration operations, the dielectric constant of the silicon-containing material may be undesirably increased and may be too high for certain transistors, such as GAA transistors.

To address dielectric constant issues, conventional approaches have addressed the introduction of —OH groups and resultant depletion of carbon in the silicon-containing materials during integration operations by further reducing the dielectric constant of the as-deposited dielectric material. However, these conventional approaches may not be able to meet the requirements of certain transistors, such as GAA transistors.

The present technology overcomes these issues by treating the silicon-containing material subsequent to integration operations. The treatment may reintroduce carbon, such as methyl (—CH₃) groups, to the carbon-depleted material. This may also increase hydrophobicity of the material. However, the treatment, which may utilize a carbon-containing precursor, may introduce a carbon-containing material to the structure, such as to an exposed portion of a metal-containing material. To address the carbon-containing material, a hydrogen-containing precursor may be used to reduce the carbon-containing material, which may be a metal-and-carbon-containing material. This may return the metal-and-carbon-containing material to a metal-containing material. The hydrogen-containing precursor may be provided during repair operations to at least partially prevent formation of carbon-containing material on the metal-containing material and/or provided after repair operations to at least partially reduce the presence of carbon-containing material on the metal-containing material.

Although the remaining disclosure will routinely identify specific processes utilizing the disclosed technology, it will be readily understood that the systems and methods are equally applicable to other processes as may occur in the described chambers or any other chamber. Accordingly, the technology should not be considered to be so limited as for use with these specific processes or chambers alone. The disclosure will discuss one possible chamber that may be used to perform processes according to embodiments of the present technology before additional variations and adjustments to this system according to embodiments of the present technology are described.

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

FIG. 2 shows a schematic cross-sectional view of an exemplary semiconductor process chamber 200, according to one or more embodiments. The semiconductor process chamber 200 may be a vapor deposition chamber that includes UV radiation for assisting a dielectric repair process. In one or more embodiments, the semiconductor process chamber 200 may be the ONYX® or the SILENA® process chamber available from Applied Materials, Inc., of Santa Clara, California. The semiconductor process chamber 200 may include a chamber body 202 and a chamber lid 204 disposed over the chamber body 202. The chamber body 202 and the chamber lid 204 may form an inner volume 206. A substrate support assembly 208 may be disposed in the inner volume 206. The substrate support assembly 208 may receive and support a substrate 210 thereon for processing.

A first UV transparent gas distribution showerhead 216 may be hung in the inner volume 206 through a central opening 212 of the chamber lid 204 by an upper clamping member 218 and a lower clamping member 220. The UV transparent glass distribution showerhead 216 may be positioned facing the substrate support assembly 108 to distribute one or more processing gases across a distribution volume 222 which is below the first UV transparent gas distribution showerhead 216. A second UV transparent showerhead 224 may be hung in the inner volume 206 through the central opening 212 of the chamber lid 204 below the first UV transparent gas distribution showerhead 216. Each of the UV transparent gas distribution showerheads 216, 224 may be disposed in a recess formed in the chamber lid 204. A first recess 226 may be an annular recess around an internal surface of the chamber lid 204, and the first UV transparent gas distribution showerhead 216 fits into the first recess 226. Likewise, a second recess 228 may receive the second UV transparent gas distribution showerhead 224.

A UV transparent window 214 may be disposed above the first UV transparent gas distribution showerhead 216. The UV transparent window 214 may be positioned above the first UV transparent gas distribution showerhead 216 forming a gas volume 230 between the UV transparent window 214 and the first UV transparent gas distribution showerhead 216. The UV transparent window 214 may be secured to the chamber lid 204 by any means, such as clamps, screws, bolts, etc.

The UV transparent window 214 and the first and second UV transparent gas distribution showerheads 216, 224 may be at least partially transparent to thermal or radiant energy within the UV wavelengths. The UV transparent window 214 may be quartz or another UV transparent material, such as sapphire, CaF₂, MgF₂, AlON, a silicon oxide material, a silicon oxynitride material, or another transparent material.

A UV source 250 may be disposed above the UV transparent window 214. The UV source 250 may be configured to generate UV energy and project the UV energy towards the substrate support assembly 208 through the UV transparent window 214, the first UV transparent gas distribution showerhead 216, and the second UV transparent gas distribution showerhead 224, thereby exposing the substrate 210 on the substrate support assembly 208 to UV light. A cover (not shown) may be disposed above the UV source 250. In one or more embodiments, the cover may be shaped to assist the projection of the UV energy from the UV source 250 towards the substrate support.

In one or more embodiment, the UV source 250 may include one or more UV lights 252 to generate UV radiation. The UV lights 252 may be lamps, LED emitters, or other UV emitters. In one or more embodiments, the UV lights 252 may be argon lamps discharging radiation at 126 nm, krypton lamps discharging at 146 nm, xenon lamps discharging at 172 nm, krypton chloride lamps discharging at 222 nm, xenon chloride lamps discharging at 308 nm, mercury lamps discharging at 254 nm or 365 nm, metal vapor lamps such as zinc discharging at 214 nm, rare earth near-UV lamps such as europium-doped strontium borate or fluoroborate lamps discharging at 368-371 nm, to name a few examples.

The semiconductor process chamber 200 may include flow channels 232, 234, 236 configured to supply one or more processing gases across the substrate support assembly 208 to process a substrate 210 disposed thereon. A first flow channel 232 provides a flow pathway for gas to enter the gas volume 230 and to be exposed to UV radiation from the UV source 250. The gas from the gas volume 230 may flow through the first UV transparent gas distribution showerhead 216 into the distribution volume 222. A second flow channel 234 may provide a flow pathway for precursor compounds and gases to enter the distribution volume 222 directly without passing through the first UV transparent gas distribution showerhead 216 to mix with the gas that was previously exposed to UV radiation in the gas volume 230. The mixed gases in the distribution volume 222 may be further exposed to UV radiation through the first UV transparent gas distribution showerhead 216 before flowing through the second UV transparent gas distribution showerhead 224 into a space proximate the substrate support assembly 208. The gas proximate the substrate support assembly 208, and a substrate disposed on the substrate support assembly 208, is further exposed to the UV radiation through the second UV transparent gas distribution showerhead 224. Purge gases may be provided through an opening 238 in the bottom of the semiconductor process chamber 200 such that the purge gas flow around the substrate support assembly 208, preventing intrusion of processing gases into the space under the substrate support assembly 208. One or more gases may be exhausted through the opening 238.

The first UV transparent gas distribution showerhead 216 may include a plurality of holes 240 that allow processing gas to flow from the gas volume 230 to the distribution volume 222. The second UV transparent gas distribution showerhead 224 may also include a plurality of holes 242 that allow processing gas to flow from the distribution volume 222 into the processing space proximate the substrate support assembly 208. The holes 240, 242 in the first and second UV transparent gas distribution showerheads 216, 224 may be evenly distributed or irregularly spaced.

A purge gas or carrier gas source 254 may be coupled to the first flow channel 232 through a conduit 256. Purge gas or carrier gas from the purge or carrier gas source 254 may be provided through the first flow channel 232 during substrate processing to prevent intrusion of process gases into the gas volume 230. A cleaning gas source 274 may also be coupled to the first flow channel 232 through the conduit 256 to provide cleaning of the conduit 256, the first flow channel 232, the gas volume 230, and the rest of the chamber body 202 when not processing substrates.

A process gas or precursor compound source 258 may be coupled to the second flow channel 234 through a conduit 260 to provide a mixture, as described above, to the chamber body 202. The process gas or precursor compound source 258 may also be coupled to a third flow channel 236. Appropriate valves may allow selection of one or both of the flow channels 234, 236 for flowing the process gas mixture into the chamber body 202.

Substrate temperature may be controlled by providing heating and cooling features in the substrate support assembly 208. A coolant conduit 264 may be coupled to a coolant source 270 to provide a coolant to a cooling plenum 262 disposed in the substrate support assembly 208. One example of a coolant that may be used is a mixture of 50% ethylene glycol in water, by volume. The coolant flow is controlled to maintain temperature of the substrate at or below a desired level to promote deposition of UV-activated oligomers or fragments on the substrate. A heating element 266 may also be provided in the substrate support assembly 208. The heating element 266 may be a resistive heater, and may be coupled to a heating source 272, such as a power supply, by a conduit 268. The heating element 266 may be used to heat the substrate during the hardening process described above.

FIG. 3 shows exemplary operations in a semiconductor processing method 300, according to some embodiments of the present technology. The method may be performed in a variety of processing chambers, including semiconductor processing chamber 200 described above. Method 300 may include one or more operations prior to the initiation of the stated method operations, including front end processing, deposition, etching, polishing, cleaning, or any other operations that may be performed prior to the described operations. The method may include a number of optional operations, as denoted in the figure, which may or may not specifically be associated with the method, according to the present technology. For example, many of the operations are described in order to provide a broader scope of the semiconductor process, but are not critical to the technology, or may be performed by alternative methodology as will be discussed further below.

Method 300 may involve optional operations to develop the semiconductor structure to a particular fabrication operation. Although, in some embodiments, method 300 may be performed on a base structure, in some embodiments the method may be performed subsequent to other material formation or removal. For example, any number of deposition, masking, or removal operations may be performed to produce any transistor, memory, or other structural aspects on a substrate. The substrate may be disposed on a substrate support, which may be positioned within a processing region of a semiconductor processing chamber. The operations may be performed in the same chamber in which aspects of method 300 may be performed, and one or more operations may also be performed in one or more chambers on a similar platform as a chamber in which operations of method 300 may be performed, or on other platforms. Method 300 describes the operations shown schematically in FIGS. 4A-4C, the illustrations of which will be described in conjunction with the operations of method 300. It is to be understood that FIGS. 4A-4C illustrate only partial schematic views, and a substrate may contain any number of transistor sections having aspects as illustrated in the figures.

As shown in FIG. 4A, structure 400 may include a substrate 405. One or more layers of material may be formed over the substrate 405. For example, a metal-containing material 410 may be disposed on the substrate 405. An etch stop layer 415 may overlay at least a portion of the metal-containing material 410. A silicon-containing material 420 may overlay at least a portion of the etch stop layer 415. A first surface of the etch stop layer 415 may be in contact with the metal-containing material 410. A second surface of the etch stop layer 415 opposite the first surface may be in contact with the silicon-containing material 420. The etch stop layer 415 may be patterned and removed to expose at least a portion the underlying metal-containing material 410. As such, an exposed region of the silicon-containing material 420 and an exposed region of the metal-containing material 410 may be present on the substrate 405.

The substrate 405 may be made of or contain silicon, germanium, a combination of silicon and germanium, or some other semiconductor substrate material. The metal-containing material 410 may be a metal, a metal-and-oxygen-containing material, or any other metal-containing material. In embodiments, the metal may be or include, but is not limited to, copper (Cu), cobalt (Co), nickel (Ni), aluminum (Al), ruthenium (Ru), molybdenum (Mo), tungsten (W), or any other metal used or useful in semiconductor processing. As such, the metal-containing material may be or include a copper-containing material, a cobalt-containing material, a nickel-containing material, an aluminum-containing material, a ruthenium-containing material, a molybdenum-containing material, or a tungsten-containing material. The etch stop layer 415 may be or include, but is not limited to, a silicon-containing material (e.g., silicon-and-nitrogen-containing material, silicon-and-oxygen-containing material, silicon-and-carbon-containing material, silicon-carbon-and-nitrogen-containing material, silicon-oxygen-and-nitrogen-containing material, etc.), an aluminum-containing material (e.g., aluminum-and-oxygen-containing material or aluminum-and-nitrogen-containing material), a boron-containing material (e.g., boron-and-nitrogen-containing material), a combination of these materials (e.g., a multi-layered stack of materials), or any other etch stop layer materials used or useful in semiconductor processing.

The silicon-containing material 420 may be a dielectric material, and may include oxygen, nitrogen, carbon, or other constituents in addition to silicon. For example, the silicon-containing material 420 may be or include a silicon-and-oxygen-containing material, a silicon-and-nitrogen-containing material, or a silicon-and-carbon-containing material. For the etch stop layer 415 to be effective, the silicon-containing material 420 may be different from the etch stop layer 415, such that an etch may slow down or stop when etching through the silicon-containing material 420 and to the etch stop layer 415. The silicon-containing material 420 may be characterized by a first dielectric constant of less than or about 3.2, and may be characterized by a dielectric constant of less than or about 3.15, less than or about 3.1, less than or about 3.05, less than or about 3.0, less than or about 2.95, less than or about 2.9, less than or about 2.85, less than or about 2.8, less than or about 2.75, less than or about 2.7, less than or about 2.65, less than or about 2.6, less than or about 2.55, less than or about 2.5, or less.

At optional operation 305, method 300 may include performing one or more integration operations. The integration operations may include, but are not limited to, an etching operation, including a dry etching operation or wet etching operation, an ashing operation, or a cleaning operation. The one or more integration operations performed at optional operation 305 may damage the silicon-containing material 420. For example, the one or more integration operations performed at optional operation 305 may remove methyl (—CH₃) groups from the silicon-containing material 420. The one or more integration operations performed at optional operation 305 may introduce hydroxyl (—OH) groups to the silicon-containing material 420. In embodiments, the one or more integration operations performed at optional operation 305 may replace at least some-CH₃ groups with —OH groups. This may decrease hydrophobicity and, therefore, increase hydrophilicity of the silicon-containing material 420.

Performing the one or more integration operations at optional operation 305 may increase the dielectric constant of the silicon-containing material 420. In embodiments, the one or more integration operations performed at optional operation 305 may increase the dielectric constant of the silicon-containing material 420 to a second dielectric constant that is greater than the first dielectric constant. The dielectric constant of the silicon-containing material 420 may be increased by greater than or about 0.1, and may be increased by greater than or about 0.15, greater than or about 0.2, greater than or about 0.25, greater than or about 0.3, greater than or about 0.35, greater than or about 0.4, greater than or about 0.45, greater than or about 0.5, or more.

At operation 310, method 300 may include providing a treatment precursor to the processing region of the semiconductor processing chamber. The treatment precursor may be a carbon-containing precursor, such as a hydrocarbon, a silicon-and-carbon-containing precursor, or an alcohol. In embodiments, the treatment precursor may be a carbon-containing precursor that is silicon-free. As such, the treatment precursor may be any precursor including carbon and may, in embodiments, also include silicon and/or oxygen, but, in embodiments, may also be free of silicon.

The treatment precursor may be any precursor from Group I-VI below:

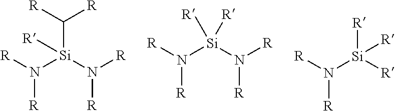

Group I. Each R may be independently selected from methyl (Me), ethyl (Et), isopropyl (iPr), tert-butyl (tBu), or hydrogen (H). Each R′ may be independently selected from an alkane, an alkene, or an alkyne with between one and twenty carbons.

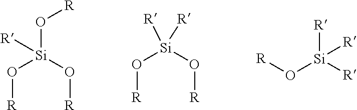

Group II. Each R may be independently selected from methyl (Me), ethyl (Et), isopropyl (iPr), tert-butyl (tBu), or hydrogen (H). Each R′ may be independently selected from an alkane, an alkene, or an alkyne with between one and twenty carbons.

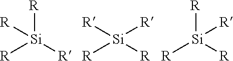

Group III. Each R may be independently selected from chlorine (CI), bromine (Br), or iodine (I). Each R′ may be independently selected from an alkane, an alkene, or an alkyne with between one and twenty carbons.

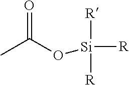

Group IV. Each R′ may be independently selected from an alkane, an alkene, or an alkyne with between one and twenty carbons.

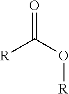

Group V. Each R may be independently selected from hydrogen (H), an alkane, an alkene, an alkyne, or an aryl. The alkane, alkene, alkyne, and the aryl may have between one and twenty carbons.

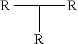

Group VI. Each R may be independently selected from hydrogen (H), an alkane, an alkene, an alkyne, or an aryl. The alkane, alkene, alkyne, and the aryl may have between one and twenty carbons.

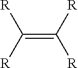

Group VII. Each R may be independently selected from hydrogen (H), an alkane, an alkene, an alkyne, or an aryl. The alkane, alkene, alkyne, and the aryl may have between one and twenty carbons.

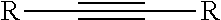

Group VIII. Each R may be independently selected from hydrogen (H), an alkane, an alkene, an alkyne, or an aryl. The alkane, alkene, alkyne, and the aryl may have between one and twenty carbons.

Some exemplary treatment precursors may be or include hexamethyldisilazane (HMDS), tetramethyldisilazane (TMDS), trimethylchlorosilane (TMCS), dimethyldichlorosilane (DMDCS), methyltrichlorosilane (MTCS), trimethylmethoxysilane (TMMS) (CH₃—O—Si—(CH₃)₃), dimethyldimethoxysilane (DMDMS) ((CH₃)₂—Si—(OCH₃)₂), methyltrimethoxysilane (MTMS) ((CH₃—O)₃—Si—CH₃), phenyltrimethoxysilane (PTMOS) (C₆H₅—Si—(OCH₃)₃), phenyldimethylchlorosilane (PDMCS) (C₆H₅—Si(Cl)—(CH₃)₂), dimethylaminotrimethylsilane (DMATMS) ((CH₃)₂—N—Si—(CH₃)₃), or bis(dimethylamino)dimethylsilane (BDMADMS), as well as any other carbon-containing precursor that may be used in semiconductor processing, such as carbon-containing precursors to introduce-CH₃ groups to silicon-containing material.

A flow rate of the treatment precursor may be adequate to interact with and treat the silicon-containing material 420. In embodiments, the flow rate of the treatment precursor may be greater than or about 100 mgm, and may be greater than or about 200 mgm, greater than or about 300 mgm, greater than or about 400 mgm, greater than or about 500 mgm, greater than or about 750 mgm, greater than or about 1,000 mgm, greater than or about 1,250 mgm, greater than or about 1,500 mgm, greater than or about 1,750 mgm, greater than or about 2,000 mgm, or more. At lower flow rates, a longer treatment time may be needed to fully treat the silicon-containing material 420, which may reduce throughput. The treatment precursor may be provided in vapor phase, which may allow the treatment precursor to penetrate deeply into the silicon-containing material 420. The vaporized treatment precursor may be vaporized prior to being provided to the processing region at operation 310 or may be vaporized in the processing region.

At optional operation 315, method 300 may include providing a hydrogen-containing precursor to the processing region of the semiconductor processing chamber. The hydrogen-containing precursor may be any precursor including hydrogen and may, in embodiments, also include other constituents, but, in embodiments, may also be free of silicon. As such, the processing region may be maintained silicon-free, such that no silicon-containing material is provided to the processing region during method 300. The hydrogen-containing precursor may be, for example, diatomic hydrogen (H₂), ammonia (NH₃), hydrazine (N₂H₄), or any other hydrogen-containing precursor used or useful in semiconductor processing.

The hydrogen-containing precursor may be provided simultaneously, or co-flowed, with the treatment precursor. Alternatively, either the hydrogen-containing precursor, the treatment precursor, or both may be pulsed, or provided discontinuously. As such, in embodiments, either the hydrogen-containing precursor or the treatment precursor may be pulsed while the other is provided continuously. However, it is also contemplated that both the hydrogen-containing precursor and the treatment precursor be provided continuously.

Operation 310 and optional operation 315 may or may not include delivery of additional precursors, such as one or more carrier gases, to assist the flow of the treatment precursor. The carrier gases may include helium, argon, or diatomic nitrogen.

In embodiments, method 300 may include forming radicals of the treatment precursor and, if provided, the hydrogen-containing precursor, at optional operation 320. The radicals may be formed using RF power or by directing an ultraviolet (UV) light source into the processing region.

When formed using RF power, the radicals of the treatment precursor and, if provided, the hydrogen-containing precursor may be formed at a plasma power of less than or about 3,000 W, and may be generated at a plasma power of less than or about 2,750 W, less than or about 2,500 W, less than or about 2,250 W, less than or about 2,000 W, less than or about 1,750 W, less than or about 1,500 W, less than or about 1,250 W, less than or about 1,000 W, less than or about 750 W, less than or about 500 W, less than or about 250 W, or less.

When formed by directing the UV light source into the processing region, conditions of the UV light source may be tailored to form radicals of the treatment precursor and, if provided, the hydrogen-containing precursor. For example, a UV irradiance power may be characterized by between about 100 W/m² and about 2000 W/m². At UV irradiance powers less than 100 W/m², the UV radiation may not be significant enough to form radicals of the treatment precursor and, if provided, the hydrogen-containing precursor. At UV irradiance powers greater than 2000 W/m², the UV radiation may damage materials, such as the silicon-containing material 420, and/or structure 400. Additionally, a UV wavelength may be characterized by between about 100 nm and about 400 nm. A UV wavelength below 100 nm may require a special light source that may not be commonly available. A UV wavelength above 400 nm, such as visible light, may not have sufficient energy to form radicals of the treatment precursor and, if provided, the hydrogen-containing precursor.

Whether formed using RF power or by directing UV light source into the processing region, the RF power or the UV light source may be pulsed, such that the source of energy is not being provided continuously. This may lower an effective power of the source of energy and control an amount of radicals of the treatment precursor and, if provided, the hydrogen-containing precursor being formed. A duty cycle, or ON time, of the RF power or the UV light source may be less than or about 95%, and may be less than or about 90%, less than or about 85%, less than or about 80%, less than or about 75%, less than or about 70%, less than or about 65%, less than or about 60%, less than or about 55%, less than or about 50%, less than or about 45%, less than or 40%, less than or 30%, less than or 20%, less than or 10%, or less. Conversely, the duty cycle of the RF power or the UV light source may be greater than or about 10%, greater than or about 20%, greater than or about 30%, greater than or about 40%, greater than or about 45%, greater than or about 50%, greater than or about 55%, greater than or about 60%, greater than or about 65%, greater than or about 70%, greater than or about 75%, greater than or about 80%, greater than or about 85%, greater than or about 90%, greater than or about 95%, or more.

Additionally, a frequency of the pulsing may be between about 10 Hz and about 20,000 Hz. For example, the frequency of the pulsing may be less than or about 20,000 Hz, and may be less than or about 15,000 Hz, less than or about 10,000 Hz, less than or about 5,000 Hz, less than or about 1,000 Hz, less than or about 750 Hz, less than or about 500 Hz, less than or about 250 Hz, less than or about 100 Hz, less than or about 50 Hz, less than or about 25 Hz, or less. Conversely, the frequency of the pulsing may be greater than or about 10 Hz, and may be greater than or about 50 Hz, greater than or about 100 Hz, greater than or about 250 Hz, greater than or about 500 Hz, greater than or about 750 Hz, greater than or about 1,000 Hz, greater than or about 2,500 Hz, greater than or about 5,000 Hz, greater than or about 10,000 Hz, greater than or about 15,000 Hz, or more.

While radicals of the treatment precursor and, if provided, the hydrogen-containing precursor may be formed in some embodiments, other embodiments may include a thermal process that does not include forming radicals of the treatment precursor and, if provided, the hydrogen-containing precursor.

At operation 325, method 300 may include contacting the substrate 405, including the silicon-containing material 420 and/or the metal-containing material 410, with the treatment precursor and, if present, the hydrogen-containing precursor or the radicals thereof. The contacting with the treatment precursor or radicals thereof may at least partially repairs the silicon-containing material 420, which may refer to an increase in an amount of —CH₃ groups in the silicon-containing material 420 or a reduction in a dielectric constant of the silicon-containing material 420. That is, the contacting may reduce silanol (Si—OH) groups and/or terminal-OH groups in the silicon-containing material 420, such as through the replacement of Si—OH groups and/or terminal-OH groups with —CH₃ groups. Therefore, the contacting may repair the silicon-containing material 420 that was damaged during optional operation 305. Additionally and/or alternatively, even when optional operation 305 may not be performed, the contacting at operation 325 may nevertheless further reduce the dielectric constant of the silicon-containing material by increasing the amount of —CH₃ groups.

When the hydrogen-containing precursor is provided at optional operation 315, the hydrogen-containing precursor or radicals thereof may reduce the metal-containing material 410 from a metal-and-oxygen-containing material to a metal-containing material. That is, the contacting may reduce and/or remove a native oxide formed on the metal-containing material 410. Additionally, the hydrogen-containing precursor or radicals thereof may reduce formation of a metal-and-carbon-containing material that may form through contact between the treatment precursor and the metal-containing material 410. That is, the contacting may reduce and/or remove a metal carbide formed on the metal-containing material 410.

The contacting at operation 325 may reduce the dielectric constant to a third dielectric constant that is less than the second dielectric constant. The third dielectric constant may be less than, equal to, or greater than the first dielectric constant. In embodiments, the third dielectric constant may be less than or about 3.0, and may be less than or about 2.95, less than or about 2.9, less than or about 2.85, less than or about 2.8, less than or about 2.75, less than or about 2.7, less than or about 2.65, less than or about 2.6, less than or about 2.55, less than or about 2.5, or less. In embodiments, contacting the substrate 405, including the silicon-containing material 420, with the treatment precursor may reduce the dielectric constant of the silicon-containing material 420 by greater than or about 10%, and may reduce the dielectric constant by greater than or about 11%, greater than or about 12%, greater than or about 13%, greater than or about 14%, greater than or about 15%, or more.

Additionally, contacting the substrate with the treatment precursor and, if present, the hydrogen-containing precursor or radicals thereof may increase a surface carbon concentration of the silicon-containing material 420 by greater than or about 5 at. %, such as greater than or about 6 at. %, greater than or about 8 at. %, greater than or about 10 at. %, greater than or about 12 at. %, greater than or about 14 at. %, greater than or about 15 at. %, greater than or about 16 at. %, greater than or about 18 at. %, greater than or about 20 at. %, or more. The increase in the surface carbon concentration of the silicon-containing material 420 may be attributed to the increase the amount of —CH₃ groups and/or the reduction of —OH groups.

In embodiments, contacting the substrate 405, including the silicon-containing material 420, with the treatment precursor may be performed for a period of time of less than or about 15 minutes. While the period of time may be partially dependent on the flow rate of the treatment precursor, adequate flow rates may allow the period of time to be less than or about 14 minutes, such as less than or about 13 minutes, less than or about 12 minutes, less than or about 11 minutes, less than or about 10 minutes, less than or about 9 minutes, less than or about 8 minutes, less than or about 7 minutes, less than or about 6 minutes, less than or about 5 minutes, less than or about 4 minutes, less than or about 3 minutes, less than or about 2 minutes, less than or about 1 minute, less than or about 50 seconds, less than or about 40 seconds, less than or about 30 seconds, or less. The period of time may also be maintained at any period of time within these ranges, within smaller ranges encompassed by these ranges, or between any of these ranges.

In embodiments, contacting the substrate with the treatment precursor and, if present, the hydrogen-containing precursor or radicals thereof may form a layer of carbon-containing material on the exposed region of the metal-containing material 410. At optional operation 330, method 300 may include performing a post-treatment operation. The post-treatment operation may include providing a hydrogen-containing precursor to the processing region, optionally forming radicals of the hydrogen-containing precursor, and contacting the substrate with the hydrogen-containing precursor or radicals thereof. The hydrogen-containing precursor provided at optional operation 330 may be or include any hydrogen-containing precursor previously discussed, such as with regard to optional operation 315. The radicals of the hydrogen-containing precursor may be formed using any of the features or methods previously discussed, such as with regard to optional operation 320. The contacting removes during the post-treatment operation at optional operation 330 may remove a carbon-containing material deposited while contacting the substrate with the treatment precursor or radicals thereof, such as during operation 325. The post-treatment operation at optional operation 330 may act similarly to providing the hydrogen-containing precursor at optional operation 315. That is, the contacting may reduce and/or remove a metal carbide formed on the metal-containing material 410.

Process conditions may impact the operations performed in method 300. Each of the operations of method 300 may be performed during a constant temperature in embodiments, while in some embodiments the temperature may be adjusted during different operations. In some embodiments of the present technology, method 300 may be performed at substrate, pedestal, and/or chamber temperatures greater than or about 75° C., and may be greater than or about 100° C., greater than or about 150° C., greater than or about 200° C., greater than or about 250° C., greater than or about 300° C., greater than or about 350° C., greater than or about 400° C., greater than or about 450° C., greater than or about 500° C., or higher. At lower temperatures, there may not be sufficient energy to drive a reaction between the treatment precursor and the silicon-containing material 420. However, higher temperatures may exceed a thermal budget of the structure 400. As such, method 300 may be performed at substrate, pedestal, and/or chamber temperatures less or about 500° C., and may be performed at temperatures less than or about 475° C., less than or about 450° C., less than or about 425° C., less than or about 400° C., less than or about 375° C., less or about 350° C., less or about 325° C., less or about 300° C., less or about 275° C., less or about 250° C., less or about 200° C., less or about 150° C., less or about 100° C., or lower. The temperature may also be maintained at any temperature within these ranges, within smaller ranges encompassed by these ranges, or between any of these ranges.

The pressure within the semiconductor processing chamber may also affect the operations performed. In embodiments, the pressure may be maintained at less than about 100 Torr. Accordingly, method 300 may be maintained at less than or about 90 Torr, and may be maintained at less than or about 80 Torr, less than or about 70 Torr, less than or about 60 Torr, less than or about 50 Torr, less than or about 40 Torr, less than or about 30 Torr, less than or about 25 Torr, less than or about 20 Torr, less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, less than or about 1 Torr, or less. The pressure may also be maintained at any pressure within these ranges, within smaller ranges encompassed by these ranges, or between any of these ranges.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the material” includes reference to one or more materials and equivalents thereof known to those skilled in the art, and so forth. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a treatment precursor to a processing region of a semiconductor processing chamber, wherein a substrate is housed within the processing region, and wherein an exposed region of a silicon-containing material and an exposed region of a metal-containing material are disposed on the substrate;
directing an ultraviolet (UV) light source into the processing region, wherein the UV light source forms radicals of the treatment precursor; and
contacting the substrate with the radicals of the treatment precursor, wherein the contacting at least partially repairs the silicon-containing material.

2. The semiconductor processing method of claim 1, wherein the treatment precursor comprises a carbon-containing precursor.

3. The semiconductor processing method of claim 1, wherein the treatment precursor comprises a hydrocarbon or an alcohol.

4. The semiconductor processing method of claim 1, wherein the treatment precursor is silicon-free.

5. The semiconductor processing method of claim 1, wherein the metal-containing material comprises a copper-containing material, a cobalt-containing material, a nickel-containing material, an aluminum-containing material, a ruthenium-containing material, a molybdenum-containing material, or a tungsten-containing material.

6. The semiconductor processing method of claim 1, wherein contacting the substrate with the radicals of the treatment precursor forms a layer of carbon-containing material on the exposed region of the silicon-containing material.

7. The semiconductor processing method of claim 1, wherein contacting the substrate with the radicals of the treatment precursor reduces a dielectric constant of the silicon-containing material by greater than or about 10%.

8. The semiconductor processing method of claim 1, wherein the dielectric constant of the silicon-containing material, subsequent to contacting the substrate with the radicals of the treatment precursor, is less than or about 3.0.

9. The semiconductor processing method of claim 1, wherein a temperature within the processing region is maintained at greater than or about 50° C.

10. The semiconductor processing method of claim 1, wherein a pressure within the processing region is maintained at less than or about 50 Torr.

11. A semiconductor processing method comprising:
providing a carbon-containing treatment precursor and a hydrogen-containing precursor to a processing region of a semiconductor processing chamber, wherein a substrate is housed within the processing region, and wherein an exposed region of a silicon-containing material and an exposed region of a metal-containing material are disposed on the substrate;
forming radicals of the carbon-containing treatment precursor and the hydrogen-containing precursor;
contacting the substrate with the radicals of the carbon-containing treatment precursor and the hydrogen-containing precursor, wherein the contacting at least partially repairs the silicon-containing material.

12. The semiconductor processing method of claim 11, wherein the carbon-containing treatment precursor is silicon-free.

13. The semiconductor processing method of claim 11, wherein the radicals of the carbon-containing treatment precursor and the hydrogen-containing precursor are formed using RF power.

14. The semiconductor processing method of claim 13, wherein the RF power is pulsed.

15. The semiconductor processing method of claim 11, wherein contacting the substrate with the radicals of the carbon-containing treatment precursor and the hydrogen-containing precursor reduces a dielectric constant of the silicon-containing material by greater than or about 0.1.

16. A semiconductor processing method comprising:
providing a carbon-containing treatment precursor to a processing region of a semiconductor processing chamber, wherein a substrate is housed within the processing region, and wherein an exposed region of a silicon-containing material and an exposed region of a metal-containing material are disposed on the substrate;
forming radicals of the carbon-containing treatment precursor;
contacting the substrate with the radicals of the carbon-containing treatment precursor, wherein the contacting at least partially repairs the silicon-containing material; and
subsequent to contacting the substrate with the radicals of the carbon-containing treatment precursor, performing a post-treatment operation comprising:
providing a hydrogen-containing precursor to the processing region;
forming radicals of the hydrogen-containing precursor; and
contacting the substrate with the radicals of the hydrogen-containing precursor, wherein the contacting removes a carbon-containing material deposited while contacting the substrate with the radicals of the carbon-containing treatment precursor.

17. The semiconductor processing method of claim 16, wherein the carbon-containing treatment precursor further comprises silicon.

18. The semiconductor processing method of claim 16, wherein the radicals of the carbon-containing treatment precursor and/or the hydrogen-containing precursor are formed using an ultraviolet (UV) light source directed into the processing region.

19. The semiconductor processing method of claim 18, wherein the UV light source is pulsed.

20. The semiconductor processing method of claim 16, wherein contacting the substrate with the radicals of the carbon-containing treatment precursor increases a surface carbon concentration of the silicon-containing material by greater than or about 10 at. %.
